(19) United States
(12) Patent Application Publication
(10) Pub. No.: US 2012/0156396 A1
(43) Pub. Date: Jun. 21, 2012

(54) CVD REACTOR

(76) Inventors: Gerhard Karl Strauch, Aachen (DE); Daniel Brien, Aachen (DE); Martin Dauelsberg, Aachen (DE)

(21) Appl. No.: 13/394,040

(22) PCT Filed: Aug. 30, 2010
(86) PCT No.: PCT/EP10/62631

§ 371 Date: Mar. 2, 2012

(30) Foreign Application Priority Data
Sep. 8, 2009 (DE) 10 2009 043 960.9

(51) Int. Cl. C23C 16/46; C23C 16/505; C23C 16/458

(52) U.S. Cl. 427/587; 118/724; 118/725; 118/723 I; 427/255.28

(57) ABSTRACT

The invention relates to a CVD reactor comprising a heatable body (2, 3) disposed in a reactor housing, a heating device (4, 17) for heating the body (2, 3) located at a distance from the body (2, 3), and a cooling device (5, 18) located at a distance from the body (2, 3). The heatable body, the heating device, and the cooling device are arranged such that heat is transferred from the heating device (4, 17) across the space between the heating device (4, 17) and the body (2, 3) to the body (2, 3), and from the body (2, 3) across the space between the body (2, 3) and the cooling device (5, 18) to the cooling device (5, 18). In order to be able to affect the surface temperature of the heated process chamber walls in a locally reproducible manner, control bodies (6, 19) can be inserted into the space between the cooling and/or heating device (4, 5, 17, 18). During the thermal treatment or between sequential treatment steps, said bodies are displaced such that the heat transport is locally affected.

The invention relates to a reactor, in particular a CVD reactor having a heatable body disposed in a reactor housing, having a heating device for heating the body which is located at a spacing from the body, and having a cooling device which is located at a spacing from the body, the cooling device being arranged so that heat is transferred from the heating device to the body across the intervening space between heating device and body, and heat is transferred from the body to the cooling device across the intervening space between body and cooling device.

The invention furthermore relates to a method for heat treatment of a substrate within a process chamber of a reactor, the process chamber forming a first and a second wall portion, in particular for deposition of a layer in a CVD reactor, the substrate being supported on a susceptor that forms the first wall of the process chamber, at least one wall portion being heated to a process temperature by a heating device that is spaced from the wall portion, and a cooling device being associated with the at least one heated wall and spaced from the wall, the cooling device being arranged so that heat is transferred from the heating device to the process chamber wall across the intervening space between heating device and heated process chamber wall, and heat is transferred from the heated process chamber wall to the cooling device across the intervening space between heated process chamber wall and cooling device.

A reactor of the generic kind is described by DE 100 43 601 A1. The reactor described here has an outer wall by which the interior space of the reactor housing is isolated in a gastight manner from the outside world. Inside the reactor housing, there is a process chamber, which is delimited downwardly by a susceptor and upwardly by a process chamber ceiling. Susceptor and process chamber ceiling are made of graphite and are heated by way of a high-frequency alternating field. The RF heating devices in question are below the susceptor or above the process chamber ceiling and have the form of a spiral-shaped coil. The coil body consists of a hollow body. The hollow body is shaped into a spiral. A cooling medium flows through the hollow body, so that the heating device is at the same time a cooling device. The alternating fields produced by the RF coils generate eddy currents in the susceptor and in the process chamber ceiling, so the susceptor and the process chamber ceiling are heated.

DE 103 20 597 A1, DE 10 2006 018 515 A1 and DE 10 2005 056 320 A1 describe similar reactors.

DE 10 2005 055 252 A1 likewise describes a device of the generic kind, in which a support plate of quartz is provided underneath a susceptor that is disposed in a process chamber, consists of graphite, and is likewise heated by an RF coil through which a coolant fluid flows. The susceptor, which is driven in rotation about a central axis, floats on this quartz plate on a gas cushion. A drive mechanism is supplied with drive gas by way of channels that run in the parting plane between the lower side of the susceptor and the upper side of the quartz plate, in order to drive in rotation, substrate holders enclosed in pockets located in the upper side of the susceptor. Here also the RF coil through which a coolant flows is spaced from the susceptor by an intervening space.

U.S. Pat. No. 5,516,283 A describes a treatment device for a multiplicity of disk-shaped substrates, in which heat transfer bodies are provided between the substrates that are stacked one over the other with a space in between.

DE 198 80 398 B4 describes a temperature-measuring device for a substrate, in which the temperature on the underside of the substrate is measured by a temperature sensor that is inserted in a sheathing part.

U.S. Pat. No. 6,228,173 B1 described a heat treatment device for heat treatment of a semiconductor substrate. Beneath a work plate, there is an annular heat compensation part for reflection of heat radiation.

US 2005/0178335 A1 relates to a temperature control arrangement for which a heat conducting gas is introduced between a heated susceptor and a cooler.

There exists the technological need to affect locally the heating of the heated process chamber wall. Hitherto the heating power was modified locally for this purpose. Because of the complexity of the HF alternating field and its dependence on the edge conditions and the power, the results are unsatisfactory.

It is an object of the invention to provide means by which the surface temperature of the heated process chamber wall portion may be affected in a locally reproducible manner.

This object is met by the invention specified in the claims, the subsidiary claims representing not only advantageous developments of the associated claims, but also in each case independent solutions to the problem.

First and foremost it is provided that one or more control bodies can be brought into the intervening space between the heated wall portion and the cooling or heating device. The control bodies may be displaced during the treatment process or between two treatment processes that follow one another, in order thereby to effect a local temperature variation on the surface of the susceptor.

The invention is based on the recognition that in a CVD reactor, as is for example described in DE 10 2005 055 252 A1, approximately 10 to 30% of the power transferred by the RF heater to the susceptor or to the heated process chamber ceiling, flows back again as heat conduction or heat radiation into the cooling device, i.e. the heating spiral through which a coolant flows. There is to be intervention in this return transport path for the heat by means of the control bodies.

Usually the processes taking place in the process chamber that is located in the reactor housing are carried out at total pressures that are greater than 1 millibar. As a result, there is, in the intermediate space between the susceptor and the heating/cooling device, a gas with a total pressure of at least 1 millibar. This is, as a rule, an inert gas, for example a noble gas, hydrogen or nitrogen. At process temperatures below 1000° C., considerable power is transferred via this gas to the spiral windings through which the coolant flows by way of heat conduction from the side of the heated wall, for example of the susceptor, that faces away from the process chamber. At higher temperatures, considerable power is transferred to these cooling bodies by heat radiation. If a control body is brought locally into the intervening space between the susceptor or process chamber ceiling and the heating/cooling device, this heat transport is affected. If the return of the heat takes place substantially by way of heat conduction, the control body preferably has a specific heat conductivity which is significantly greater that the heat conductivity of the gas in the intermediate space. Preferably the ratio between the two specific heat conductivities is at least two and in particular at least five. In this variant of the method, the return flow of heat is locally increased by pushing in a control body from outside into the intermediate space between susceptor or process chamber ceiling and heating/cooling device, so that at this position the surface temperature of the susceptor or the process chamber ceiling falls slightly. If the control body consists of an electrically insulating material, the supply of energy that takes place into the susceptor or the process chamber ceiling by way of the RF coupling is not affected. In a variant of the invention, it is provided that the control body has a reflective surface, at least on the side thereof that faces the susceptor or the process chamber ceiling. The surface is reflective for the heat radiation emitted by the susceptor or by the process chamber ceiling, so that the return of heat to the RF spiral from the susceptor or at the surface of the process chamber ceiling is reduced. In this variant, the control body preferably has a low heat conductivity. It is less than that of the gas. In this way, a local raising of the temperature at the susceptor surface is possible. It is also possible for several coaxially nested RF coils to be arranged around one another, instead of a single RF coil. These may be operated at different powers. In this way a rough adjustment of the local energy supply to the susceptor or process chamber ceiling may be achieved. The fine adjustment is then effected in the manner described above by modulation of the return heat transport from the susceptor or from the process chamber ceiling to the cooling device. In this way, zones can be provided in which an increased power is coupled into the susceptor or the process chamber ceiling. In the normal state, control bodies are disposed in the region of this zone between the heating spiral and the susceptor or process chamber ceiling. In the case of a circular heating zone, an annular control body, preferably consisting of a plurality of segments, can be provided over the entire region of this heating zone. If this control body is moved away, this leads locally to an increase in the surface temperature on the susceptor or the process chamber ceiling. In this way, for example the edges of a substrate supported on the susceptor may be more strongly heated that the central region of the susceptor. In this way, a “dishing” of the substrate, i.e. a bending up of the edges, is countered. This is even possible when, in the case of a circular susceptor, the substrates are supported on substrate holders arranged around the center of the susceptor, these substrate holders, as described in DE 10 2005 055 252 A1, each carrying a substrate and rotating about their axis. In this case, there needs to be modulated only a heating zone that is underneath the edge region of the substrate holder, radially outwardly or radially inwardly. In similar manner, the surface temperatures on annular zones of the surface of the process chamber ceiling that faces the process chamber can be reduced or raised.

By means of the solution according to the invention, a heater is specified, the heat output of which can be affected locally by simple means so that thereby the temperature homogeneity can be adjusted, in particular on a susceptor surface. The modulation is robust and low-maintenance in respect of its control. There is necessary only a rough pre-adjustment by selection and disposition of the RF coils through which a cooling fluid flows. The adjustment is effected for this substantially by the spacing to the susceptor. Irregularities which may for example occur within the surface temperature distribution on the susceptor because of the spiral-shaped configuration of the RF coils can likewise be compensated for by control bodies that are suitably formed and located. The higher the susceptor temperature, the stronger is the reverse coupling of the temperature into the heating coils.

Exemplary embodiments of the invention will be described below with reference to accompanying drawings in which:

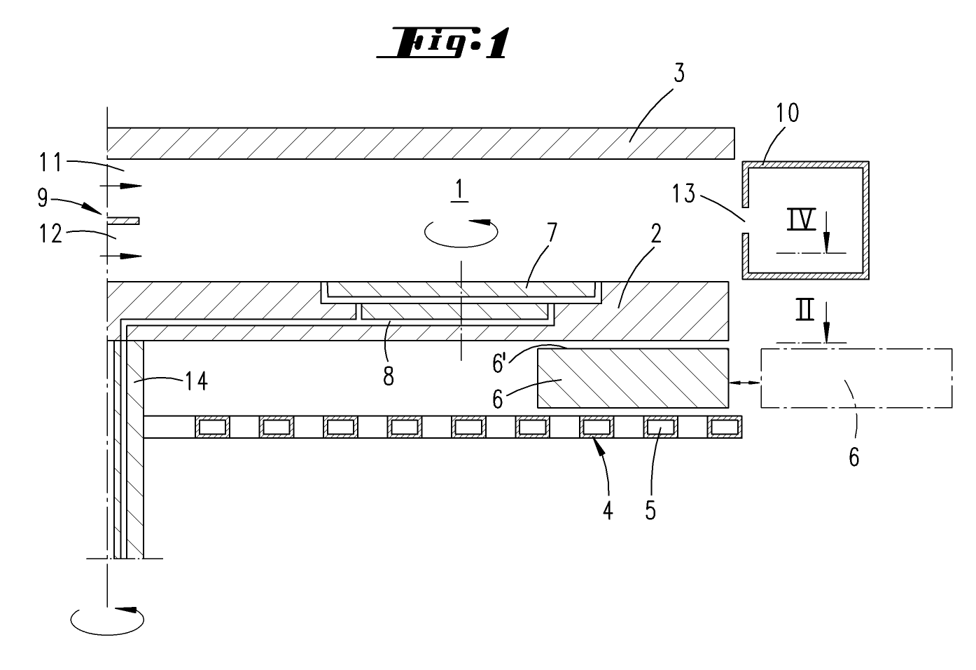

FIG. 1 shows a half cross-section through a process chamber of a CVD reactor, the wall of the reactor being left out to facilitate the view;

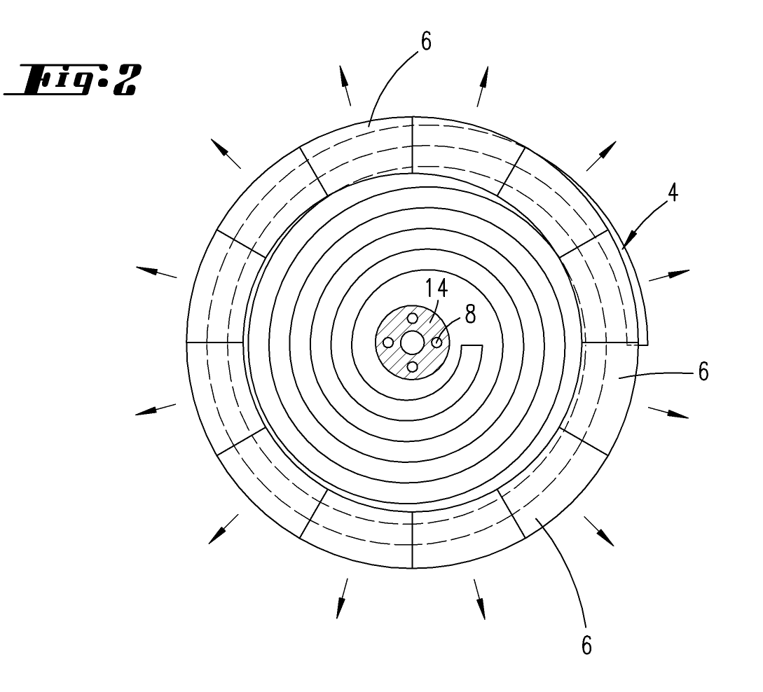

FIG. 2 shows a section on the line II-II in FIG. 1, the control bodies being in their active position;

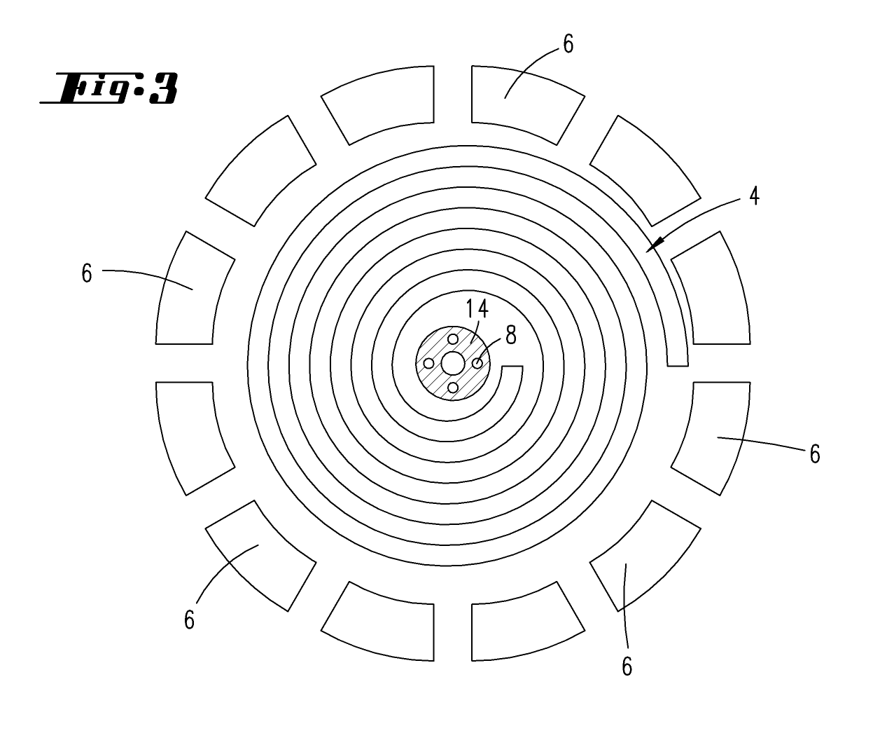

FIG. 3 shows an illustration corresponding to FIG. 2, with the control bodies brought into a non-active position;

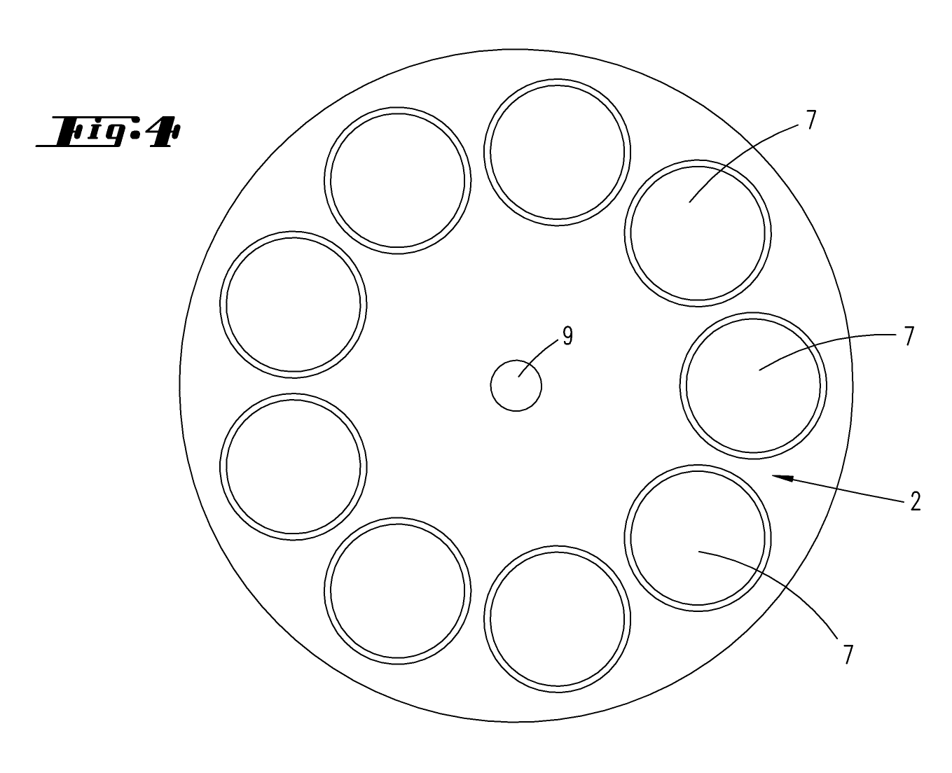

FIG. 4 shows a section on the line IV-IV in FIG. 1;

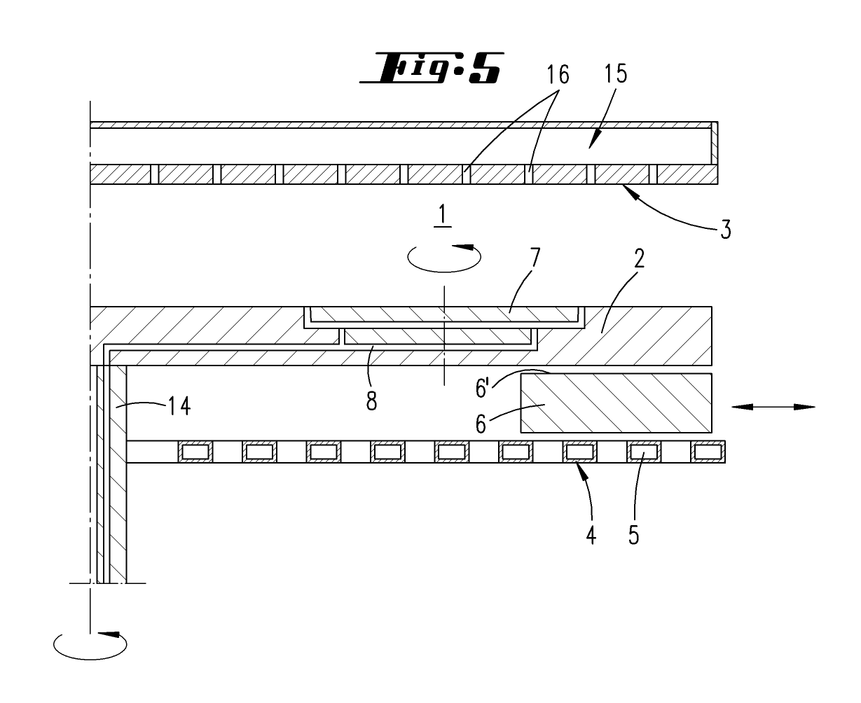

FIG. 5. shows a second exemplary embodiment of the invention with a process chamber ceiling formed by a shower head, and

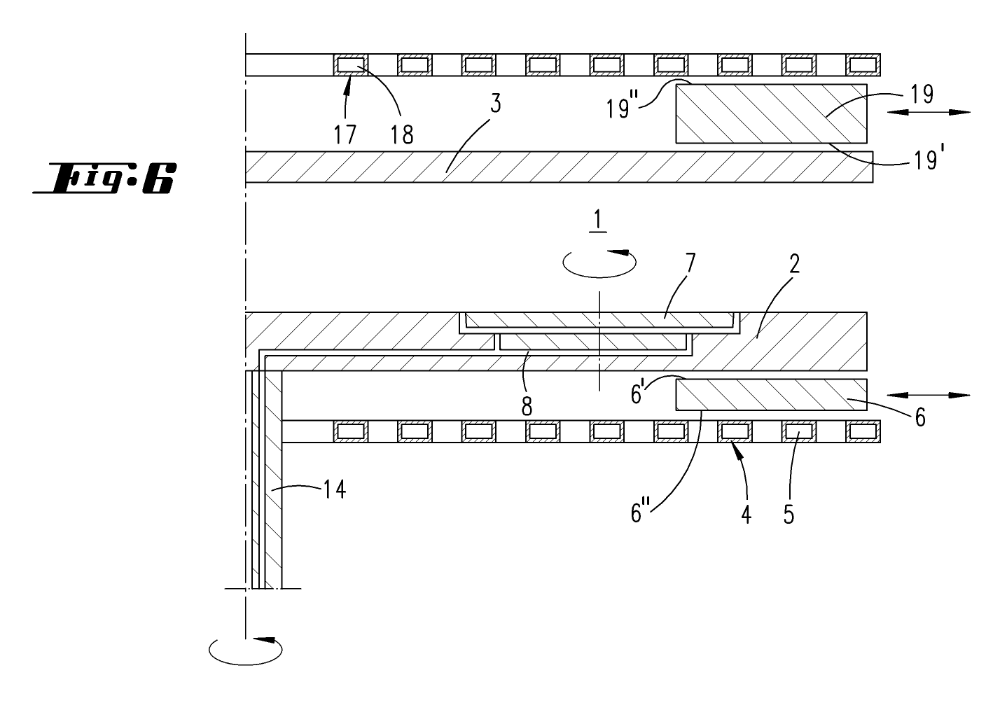

FIG. 6 shows a third exemplary embodiment of the invention, in which the process chamber ceiling 3, which is opposite the susceptor 2, is heatable.

In order to facilitate the view, there is illustrated schematically in the drawings only the process chamber 1, disposed in the interior of a reactor housing, with its floor 2, ceiling 3, and further units for explanation of the invention.

The process chamber 1 and the units shown in the Figures are inside a reactor housing made of stainless steel. Feed lines for the process gases and for the heat energy for operation of the heaters 4, 17 disposed in the reactor housing are provided through the walls of the reactor housing, which is not shown. Discharge lines for used process gases and a feed line and a discharge line for a coolant are also provided, the latter in order to bring coolant, which flows through a cooling channel 5, 18, into the reactor housing and out of the reactor housing. The reactor housing is gastight to the outside, so that it can be evacuated by means of a vacuum pump, likewise not shown, and held at a defined total inner pressure.

The first exemplary embodiment shown in FIGS. 1 to 4 has a susceptor 2 which is formed by a one-piece or multi-part graphite disk. The susceptor 2 that has the shape of a disk is rotatable about a central axis, which lies in a pillar 14. For this, the pillar 14 can be driven in rotation by a rotary drive. Within the pillar 14 and the susceptor 2, there are gas feed lines 8, which end in recesses in the upper side of the susceptor 2 that faces the process chamber 1. In these recesses, there is in each case a disk-shaped substrate holder 7. The substrate holders 7 can be rotated, held in a floating manner, by means of a gas jet directed out of the outlet openings. One or more substrates are supported on the substrate holders 7 and are heat-treated in the process chamber 1.

The heat treatment may be a coating process. This may be a CVD process, preferably an MOCVD process, in which reactive process gases together with a carrier gas are introduced into the process chamber 1 through a gas inlet element 9, which is at the center of the process chamber 1. As regards process gases, this may be a hydride, for example NH₃, that is introduced into the process chamber through the feed line 12, which is immediately above the susceptor 2. Through the feed line located above the line 12, an organometallic substance, for example TMGa or TMIn, is introduced into the process chamber 1 as a process gas.

While the process chamber 1 is delimited downwardly by the susceptor 2, the process chamber 1 is delimited upwardly by a process chamber ceiling 3. Process chamber ceiling 3 and susceptor 2 may consist of graphite.

The process gas introduced into the process chamber 1 through the gas inlet element 9 decomposes substantially only on the surface of a substrate disposed on the substrate holder 7. The substrate has a surface temperature suitable for the decomposition to take place there in a pyrolytic manner. The products of decomposition build up on the substrate surface with a single crystal III-V layer being formed.

In order to heat the susceptor 2, an RF heater is provided, which consists of a tube 4 bent into a spiral. This tube 4, which is bent into the shape of a spiral, is in a parallel plane, below the susceptor 2. There is an intervening space between the RF heater 4 and the underside of the susceptor 2. The tube forms a cooling channel 5, through which there flows a coolant, for example water. The high-frequency alternating field generated by the RF coil 4 excites eddy currents in the electrically conducting susceptor 2. These eddy currents generate heat in the susceptor 2 on account of its electrical resistance, so that the susceptor 2 is heated up to process temperatures below 1000° C. or above 1000° C. Typically the temperatures to which the susceptor 2 is heated are above 500° C.

The volatile reaction products and the carrier gas move radially outwards from the circular process chamber and are transported away by means of a gas outlet annulus 10. The gas outlet annulus 10 which is formed by a hollow body provides openings 13, through which the gas can enter into the gas outlet annulus 10. The gas outlet annulus 10 is connected to the vacuum pump, already mentioned above.

The electromagnetic alternating field generated by the RF coil 4 has a spatial configuration which is not solely dependent on the geometry and the material properties of the elements enclosing the process chamber 1. The spatial formation of the electromagnetic alternating field also depends on the power supplied to the RF heating spiral. As a result of this, the temperature profile on the surface of the susceptor 2 that faces the process chamber 1 can be only roughly adjusted by the configuration of the RF heating spiral 4, i.e. by the spacing of the coil windings or the like. The power coupled into the susceptor 2 by way of the RF field is taken away within the process chamber 1 from the susceptor 2 via heat radiation and by way of heat conduction via the carrier gas. In regard to the latter, the heat is taken away in the direction of the process chamber ceiling 3. The ceiling is heated by the heat given off by the susceptor 2, in so far as it is not itself actively heated.

A considerable part of the RF energy absorbed by the susceptor 2 is however also given off by the underside of the susceptor 2 in the direction of the cooled RF heating spiral 4. The intermediate space between heating spiral 4 and susceptor 2 is flushed by a purging gas, for example hydrogen or nitrogen. For the total pressures there, which are typically above a millibar, there is given off an appreciable amount of heat from the susceptor 2 by way of heat conduction to the heating spiral 4, where the heat is drawn off by the cooling medium flowing through the cooling channel 5.

Control bodies 6 are provided. In the exemplary embodiment, these are annular segments, which are displaceable in the radial direction relative to the center of the process chamber from an inactive position into an active position. The annular segments 6 are shown in plan view in FIG. 2 and in cross-section in FIG. 1. FIG. 3 shows the control bodies 6 in their inactive position in plan view. The control body in FIG. 1 is shown in its inactive position in chain-dashed manner. The control bodies 6, which together make up a circle in the active position, consist of a material that has a significantly greater heat conductivity than the gas in the intervening space. In the exemplary embodiment shown in FIG. 1, the control body 6 has a material thickness that is significantly greater than one-half of the height of the intervening space. The control body 6 consists here of quartz, sapphire, glass or another similar, electrically non-conductive material. On its cross-section, the control body 6 thus forms a heat-conducting path that has a higher heat-conducting capability that the same path without control bodies. The displacement of the control body 6 from the inactive position shown chain-dashed in FIG. 1 into the active position shown in solid outline thus leads to an increased return transport of heat from the susceptor 2 to the heating spiral 4 within the zone of the susceptor 2 covered by the control body 6. This results in a local cooling effect on the surface of the susceptor 2. The control bodies 6, which together form a ring according to FIG. 2, lie in a radially outer zone underneath the susceptor 2 and underneath an edge of the substrate holder 7. Since the substrate holder 7 rotates about an axis which lies outside the control body 6, only an edge portion of the substrate supported on the substrate holder 7 is cooled. Since the substrate holder 7 rotates about its axis of rotation 7, the local drop in temperature at the radially outer region of the susceptor leads to a reduction in the temperature of the substrate on the entire edge of the circular substrate that extends substantially over the whole surface of the substrate holder 7. In this way, any distortion of the substrate is avoided.

The control bodies 6 may, during a coating process, be moved to and fro between the two positions shown in FIGS. 2 and 3, by means of mechanical drives, not illustrated, which may be operated by a motor.

In the exemplary embodiment shown in FIG. 5, the same reference numerals designate the same elements of a process chamber. In this exemplary embodiment, the process chamber ceiling 3 does not consist of a one-piece or multi-part solid graphite plate. Here the process chamber ceiling 3 has a multiplicity of outlet openings arranged in the manner of a sieve. The process chamber ceiling 3 is here formed by a “shower head” 15. The process gas is introduced into the process chamber through the outlet openings 16.

In this exemplary embodiment also, there is, between the susceptor 2 and the heating spiral 4 disposed below the susceptor, a control body 6 that can be changed as to its location and has a high heat conductivity, but is electrically insulating.

In the third exemplary embodiment shown in FIG. 6, the process chamber ceiling 3 is made of graphite or another electrically conductive material. Above the process chamber ceiling 3, there is at a vertical spacing likewise an RF heater 17, which is formed by a tube bent into a spiral. The tube forms a cooling channel 18 through which a cooling medium flows. Between the RF heating spiral and the process chamber ceiling 3, there is a control body 19 of quartz, glass, sapphire or another suitable material that has a high specific heat conductivity but is electrically insulating. Here also a multiplicity of control bodies 19 may be provided, which in the active position shown in FIG. 6 together make up a closed circle.

A control body 6 is here likewise provided between susceptor 2 and RF heating spiral 4. The control bodies 19, 6 may be brought between an active position, in which they are outside the process chamber 1 in plan view, into an active position in which they lie with the process chamber 1 as seen in plan view.

In a variant of the invention, it is provided that the control bodies 6, 19 consist of a material which has a very low heat conductivity. Using control bodies 6, 19 formed in this way, the return transport of the heat from the susceptor 2 and from the process chamber ceiling 3 to the cooling channel 5 or 18 may be reduced.

At process temperatures between 500 and 1000° C., the heat conduction by the action of the heat transport mechanism in question is for recirculation of the heat. At higher temperatures, heat radiation predominates. In order to be able to intervene optimally in this transport, the surface 6′ of the control body 6 that faces the susceptor 2 or the surface 19′ of the control body 19 that faces the process chamber ceiling 3 may be formed to be reflective. With this configuration, the return transport of heat from the susceptor 2 or the process chamber ceiling 3 to the cooling channel 5, 18 may be reduced by pushing the control bodies 6, 19 into the intervening space between heating spiral 4, 17 and susceptor 2 or process chamber ceiling 3.

The surfaces 6″, 19″ of the control bodies 6, 19 that face the RF spiral 4, 17 may likewise be formed to be reflective. This is however not essential.

All features disclosed are (in themselves) pertinent to the invention. The disclosure content of the associated/accompanying priority documents (copy of the prior application) is also hereby included in full in the disclosure of the application, including for the purpose of incorporating features of these documents in claims of the present application.

1. A reactor, having a heatable body (2, 3) disposed in a reactor housing, having a heating device (4, 17) for heating the body (2, 3), which is located at a spacing from the body (2, 3), and having a cooling device (5, 18) which is located at a spacing from the body (2, 3), the cooling device being arranged so that heat is transferred from the heating device (4, 17) to the body (2, 3) across an intervening space between the heating device (4, 17) and the body (2, 3), and heat is transferred from the body (2, 3) to the cooling device (5, 18) across an intervening space between the body (2, 3) and the cooling device (5, 18), having one or more control bodies (6, 19) disposed in one or more of the intervening spaces, characterized in that the control bodies (6, 19) are displaceable within the one or more intervening spaces, as a consequence of which heat transport and a temperature of the body (2, 3) are affected locally.

2. A reactor according to claim 1, characterized in that the one or more control bodies (6, 19) are displaceable within the one or more intervening spaces from respective inactive positions in which the control bodies (6, 19) are outside the process chamber (1) in plan view, into respective active positions within the intervening spaces within the process chamber (1) in plan view, or between two respective active positions within the process chamber (1) in plan view.

3. A reactor according to claim 1, characterized in that the one or more intermediate spaces between the heatable body (2, 3) and the cooling device (5, 18) can be filled with a gas which has a first specific heat conductivity, and the control bodies (6, 19) have a second specific heat conductivity, which is different from the first specific heat conductivity by at least a factor of two or five.

4. A reactor according to claim 1, characterized in that the heatable body (2, 3) is formed by a susceptor which defines a first wall portion of a process chamber (1) and is for receiving a substrate to be treated thermally or is formed by a second wall portion of the process chamber (1) that is located opposite from and at a spacing from the susceptor.

5. A reactor according to claim 4, characterized in that the heating device (4, 17) is formed by an RF coil and the cooling device is formed by a cooling channel in the RF coil.

6. A reactor according to claim 5, characterized in that the RF coil (4) is arranged in the shape of a spiral in a plane beneath the susceptor, the susceptor extending in a horizontal plane, and the one or more control bodies are arranged to be displaceable, in between the susceptor and RF coil (4), in a plane parallel to said horizontal plane.

7. A reactor according to claim 5, characterized in that the RF coil is arranged in the shape of a spiral in a plane above a process chamber ceiling, the ceiling being opposite the susceptor and extending in a horizontal plane, and the one or more control bodies are arranged to be displaceable, in between the process chamber ceiling and the RF coil, in a plane parallel to said horizontal plane.

8. A reactor according to claim 1, characterized in that the one or more control bodies (6, 19) are electrical insulators and consist of quartz.

9. A reactor according to claim 1, characterized in that a surface (6′, 6″, 19′, 19″) of the one or more control bodies (6, 19) that faces the heatable body (2, 3) or the heating device (4, 17) is reflective.

10. A method for heat treatment of a substrate within a process chamber of a reactor, the process chamber forming a first and a second wall portion, in particular for deposition of a layer on a substrate being supported on a susceptor that forms the first wall of the process chamber, at least one wall portion being heated to a process temperature by a heating device that is spaced from the wall portion, and a cooling device being associated with the heated wall and spaced from the heated wall, the cooling device being arranged so that heat is transferred from the heating device to the process chamber wall across an intervening space between the heating device and the heated process chamber wall, and heat is transferred from the heated process chamber wall to the cooling device across an intervening space between the heated process chamber wall and the cooling device, characterized in that during a thermal treatment and/or between treatment steps that follow one another in time, one or more control bodies are displaced in at least one of the intervening spaces between the cooling or heating device and the heated process chamber wall in such a way that heat transfer is affected locally for local effect on a temperature of a surface of the heated wall portion that faces the process chamber (1).

11. The method according to claim 10, characterized in that in an intermediate space between the first wall portion or the second wall portion and the cooling device, there is a gas which has a first specific heat conductivity, and the one or more control bodies have a second specific heat conductivity which is different from the first specific conductivity by at least a factor of two.

12. The method according to claim 11, characterized in that the gas is hydrogen, nitrogen or a noble gas, and a total pressure within the intermediate space is in a range between one and one thousand millibar, the one or more control bodies consists of quartz, sapphire or glass, and the heated wall portion is formed by a graphite body.

13. The method according to claim 10, characterized in that the heating device is a spiral-shaped RF heater formed by a tube, and a cooling fluid flows through a cooling channel formed by the tube.
